(19) United States
(12) Patent Application Publication
(10) Pub. No.: US 2025/0309384 A1
(43) Pub. Date: Oct. 2, 2025

(54) BATTERY INSPECTION APPARATUS AND INSPECTION METHOD OF THE SAME

(71) Applicant: SK On Co., Ltd., Seoul (KR)

(72) Inventors: Ju Hyeon LEE, Daejeon (KR); Yong Jung KIM, Daejeon (KR); Kang KIM, Daejeon (KR); Mun Gyo SONG, Daejeon (KR)

(21) Appl. No.: 19/091,823

(22) Filed: Mar. 27, 2025

(30) Foreign Application Priority Data
Apr. 1, 2024 (KR) 10-2024-0044157

(51) Int. Cl. H01M 10/48; H01M 10/04; H01M 10/0585

(52) U.S. Cl. CPC H01M 10/48; H01M 10/0404; H01M 10/0585

(57) ABSTRACT

The present disclosure relates to a battery inspection apparatus including a grip detachably fixed to a separator located at an outermost layer of an electrode assembly and separating the separator by moving along a predetermined separation path in the electrode assembly, the electrode assembly being formed by alternately stacking a first electrode and a second electrode having a different electrical polarity from the first electrode between the separator in a predetermined stacking direction, a separation unit separating the first electrode and the second electrode from the electrode assembly according to separation of the separator, and a sensing unit located in the separation path and sensing damage to electrical insulation in the separator moved by the grip, and an inspection method the battery inspection apparatus.

### CROSS-REFERENCE TO RELATED PATENT APPLICATION

The present application claims priority under 35 U.S.C. § 119(a) to Korean patent application number 10-2024-0044157 filed on Apr. 1, 2024, the entire disclosure of which is incorporated by reference herein.

### BACKGROUND

### 1. Field

The present disclosure relates to a battery inspection apparatus and an inspection method the same. More specifically, the present disclosure relates to a battery inspection apparatus for reducing a defect rate in a battery manufacturing process and an inspection method of the same.

### 2. Description of the Related Art

An electrode assembly including a separator may undergo a voltage resistance test (e.g., a Dielectric Withstand Voltage Test or Hi-pot Test) before the electrode assembly is accommodated in a case of a battery cell. When the electrode assembly fails to pass the voltage resistance test due to the inflow of foreign substances, detachment of the electrode, or damage to the separator, it is necessary to inspect the damaged part (or burn mark) of the separator after dismantling the electrode assembly to determine which part of the separator was damaged.

The usual inspection method has a problem in that it takes a lot of time because the worker conducts disassembly analysis. There is a problem in that it is difficult to analyze the cause of the defect because the inspection time that takes a long time makes it impossible to conduct a full investigation. In addition, there is a risk of being unidentified even though there were burn marks depending on the skill level of the worker. In addition, among the charge-fail type defects, if the cause of the defect in the separator is a defect caused by a fine pin-hole, there is a problem that even a skilled worker cannot visually identify it.

### SUMMARY

According to one aspect of the present disclosure, an object is to improve a manufacturing process of a battery cell to improve the productivity of the battery cell.

According to another aspect of the present disclosure, an object is to improve the lifetime of the battery cell.

According to another aspect of the present disclosure, an object is to reduce the time required to identify the cause of defect of a separator in the manufacturing process of the battery cell, and to analyze the cause of defect through a large amount of sample investigation or a complete investigation.

According to another aspect of the present disclosure, an object is to inspect the damage of the separator regardless of the skill level of the worker.

According to another aspect of the present disclosure, an object is to automate a battery cell inspection method and detect damage of a fine separator which cannot be determined by an operator.

A battery inspection apparatus according to the present disclosure may be widely applied in the field of green technology such as electric vehicles, battery charging stations, energy storage systems (ESS), and other battery-based photovoltaics and wind power. In addition, the battery inspection apparatus according to the present disclosure may be used for eco-friendly mobility, including electric vehicles and hybrid vehicles, to prevent climate change by restraining air pollution and greenhouse gas emissions.

In order to solve the above problems, a battery inspection apparatus according to the present disclosure may include a grip detachably fixed to a separator located at an outermost layer of an electrode assembly and separating the separator by moving along a predetermined separation path in the electrode assembly, the electrode assembly being formed by alternately stacking a first electrode and a second electrode having a different electrical polarity from the first electrode between the separator in a predetermined stacking direction; a separation unit separating the first electrode and the second electrode from the electrode assembly according to separation of the separator; and a sensing unit located in the separation path and sensing damage to electrical insulation in the separator moved by the grip.

According to an embodiment, the sensing unit may include a first sensing unit configured to sense one surface of both surfaces of the separator moved by the grip; and a second sensing unit configured to sense an other surface of the both surfaces of the separator.

According an embodiment, each of the first sensing unit and the second sensing unit may include a photographing unit configured to photograph the separator.

According to an embodiment, the grip may move to a predetermined target position along the separation path and may wind the separator moved by the grip through rotation.

According to an embodiment, the separation unit may include a first electrode separation unit configured to separate the first electrode exposed externally along the stacking direction when the separator is separated; and a second electrode separation unit configured to separate the second electrode exposed externally along the stacking direction when the separator is separated.

According to an embodiment, the first electrode separation unit and the second electrode separation unit may separate the first electrode and the second electrode, respectively, by a pick and place method.

According to an embodiment, the first electrode separation unit and the second electrode separation unit may be configured to move the first electrode and the second electrode in different directions from each other when the first electrode and second electrode are separated.

According to an embodiment, the first electrode separation unit may stack the first electrode in a predetermined first storage space, and the second electrode separation unit may stack the second electrode in a predetermined second storage space.

Meanwhile, the battery inspection apparatus according the present disclosure may further include an input/output unit receiving a user's command or displaying a result of receiving and performing the user's command; and a control unit controlling the grip, the separating unit, the sensing unit, and the input/output unit, wherein the control unit may be configured to detect an area in which electrical insulation is damaged in the separator by the sensing unit, and display information on the damaged area by the input/output unit.

The battery inspection apparatus according the present disclosure may further include a roller unit configured to support movement of the separator along the separation path.

According to an embodiment, the roller unit may include a moving roller unit configured to change a position of the separator separated by the grip based on the first electrode and the second electrode exposed externally along the stacking direction when the separator is separated.

Meanwhile, a method of inspecting a battery apparatus according to the present disclosure may include gripping a portion of the separator located on an outermost layer of the electrode assembly by a grip; separating the first electrode and the second electrode through a separation unit according to separation of the separator by the grip; and inspecting damage to electrical insulation in the separator moved by the grip through a sensing unit located in a separation path.

The inspecting method of the battery inspection apparatus of the according to an embodiment, in the separating of the first electrode and the second electrode through the separation unit, the first electrode and the second electrode exposed externally along the stacking direction may be separated through a first electrode separation unit separating the first electrode and a second electrode separation unit separating the second electrode in the separation unit, respectively.

In addition, the inspecting method of the battery inspection apparatus of the according to an embodiment may further include stacking or winding the separator moved by the grip through the grip.

The inspecting method of the battery inspection apparatus of the according to an embodiment may further include displaying information including a region where electrical insulation is damaged in the separator through the sensing unit.

Meanwhile, the information including a region where electrical insulation is damaged may include coordinates in a first direction and a second direction perpendicular to the stacking direction and perpendicular to each other, and a stacking order of the first electrode and the second electrode in the stacking direction.

According to an embodiment of the present disclosure, the efficiency of a manufacturing process of a battery cell may be improved.

According to another embodiment of the present disclosure, the lifetime of the battery cell may be improved.

According to another embodiment of the present disclosure, the time required to identify the cause of defect of a separator in the manufacturing process of the battery cell may be reduced, and it may be possible to analyze the cause of defect through a large amount of sample investigation or a complete investigation.

According to another embodiment of the present disclosure, it may be possible to inspect the damage of the separator regardless of the skill level of the worker.

According to another embodiment of the present disclosure, it may be possible to automate a battery cell inspection method and detect damage of a fine separator which cannot be determined by an operator.

### BRIEF DESCRIPTION OF THE DRAWINGS

FIG. 1 illustrates an example of an electrode assembly and a battery cell including the electrode assembly.

FIG. 2 illustrates an example of a process in which an inspection device according to the present disclosure is used in a manufacturing process of a battery.

FIG. 3 schematically illustrates an example of a battery inspection apparatus and a step of an inspection method of the battery inspection apparatus according to the present disclosure.

FIG. 4 illustrates a control block diagram of the battery inspection apparatus according to the present disclosure.

FIG. 5 schematically illustrates another step of the inspection method of the battery inspection apparatus according to the present disclosure.

FIG. 6 schematically illustrates another step of the inspection method of the battery inspection apparatus according to the present disclosure.

FIG. 7 schematically illustrates another step of the inspection method of the battery inspection apparatus according to the present disclosure.

FIG. 8 schematically illustrates another step of the inspection method of the battery inspection apparatus according to the present disclosure.

FIG. 9 is a flowchart illustrating the inspection method of the battery inspection apparatus according to the present disclosure.

FIG. 10 illustrates the results according to the inspection method of the battery inspection apparatus according to the present disclosure.

### DETAILED DESCRIPTION

Hereinafter, referring to the accompanying drawings, preferred embodiments of the present disclosure will be described in detail. The configuration of a device or a control method described below is intended to illustrate embodiments of the present disclosure and is not intended to limit the scope of the present disclosure, and reference numbers used identically throughout the specification represent identical components.

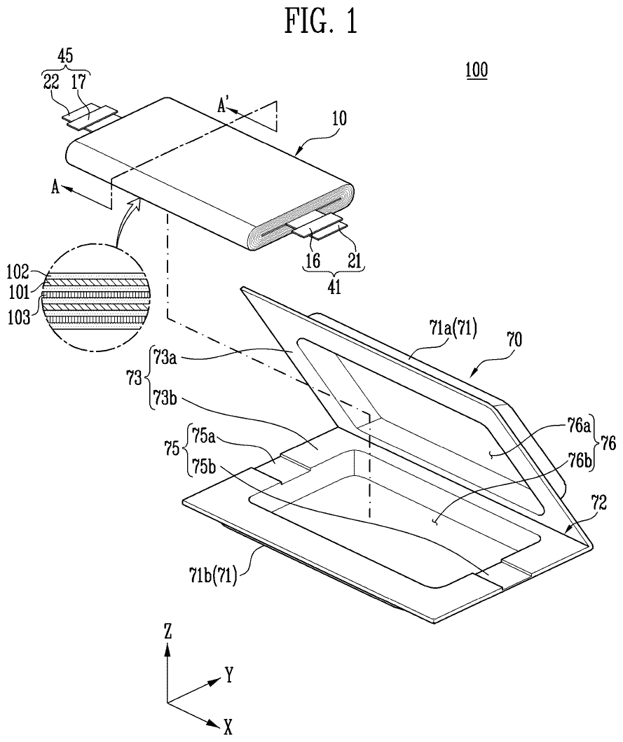

FIG. 1 illustrates an example of an electrode assembly 10 and a battery cell 100 including the electrode assembly.

Referring to FIG. 1, the battery cell 100 according to the present disclosure may include the electrode assembly 10 that produces or stores electrical energy, a case 70 that accommodates the electrode assembly 10, and lead tab portions 41 and 45 that are electrically connected to the electrode assembly 10 and protrude to the outside of the case 70.

Referring to a cross-section of the electrode assembly 10 cut along A-A′, the electrode assembly 10 may include a first electrode 101 that forms one of an anode and a cathode, a second electrode 103 that is disposed to face the first electrode 101 and forms the other electrode, and a separator 102 that is disposed between the first and second electrodes 101 and 103. The first electrode 101 and the second electrode 103 may include a plurality of first electrodes 101 and a plurality of second electrodes 103, respectively, and may be stacked in a predetermined stacking direction. The separator 102 may be disposed between each of the plurality of first electrodes 101 and the plurality of second electrodes 103 to separate the first electrode 101 and the second electrode 103.

Referring to FIG. 1, the separator 102 may be located on an outermost layer of the electrode assembly 10.

On the other hand, FIG. 1 illustrates an example in which the first electrode 101 and the second electrode 103 are alternately stacked sequentially in the electrode assembly 10 in the predetermined stacking direction, but unlike those shown in FIG. 1, the second electrode 103 and the first electrode 101 may be alternately stacked sequentially.

The lead tab portions 41, 45 may include lead tabs 21, 22 electrically connected to the first electrode 101 and the second electrode 103, respectively, and lead films 16, 17 extending in a second direction perpendicular to the stacking direction and a first direction in which the lead tab portions 41,45 protrude, and enclosing a portion of the lead tab portions 41, 45.

More specifically, the lead tab portions 41, 45 may include the lead tabs 21, 22 connected to each lead (not shown) of the plurality of first electrodes 101 and each lead (not shown) of the plurality of second electrodes 103. In addition, the lead films 16, 17 may surround the lead tabs 21, 22 at positions overlapping with a folding portion 73 to be described later.

The lead films 16, 17 may be located between the lead tabs 21, 22 and the case 70, so that the folding portion 73 to be sealed better. The lead films 16, 17 may include a polymer material such as polypropylene.

The case 70 may include a first body 71a and a second body 71b that form an accommodation space 76 for accommodating the electrode assembly 10. The first body 71a and the second body 71b may not be separate members, but may be components in which one sheet-shaped member 71 is folded and separated. That is, the one sheet-shaped member 71 may be folded with respect to a folding line 72 to form the first body 71a and the second body 71b, respectively.

The first body 71a may include a first recessed space 76a that is recessed to form a portion of the accommodation space 76. Similarly, the second body 71b may form a second recessed space 76b recessed in a direction opposite to the direction in which the first recessed space 76a is recessed to form the portion of the accommodation space 76.

When the first body 71a and the second body 71b are folded with respect to the folding line 72, the first recessed space 76a and the second recessed space 76b may form the one accommodation space 76 by combining openings of the both spaces.

The first body 71a may further include a first contact portion 73a that surrounds a circumference of the first recessed space 76a and extends in a direction perpendicular to the stacking direction. The second body 71b may further include a second contact portion 73b that surrounds a circumference of the second recessed space 76b and extends in the direction perpendicular to the stacking direction. The first contact portion 73a and the second contact portion 73b may be collectively referred to as the folding portion 73.

When the first body 71a and the second body 71b are folded with respect to the folding line 72 to form the accommodation space 76, the first contact portion 73a and the second contact portion 73b may be in contact with each other to be sealed. The leakage of an electrolyte (not shown) injected into the receiving space 76 may be prevented.

Meanwhile, the lead tab portions 41, 45 may protrude to the outside of the case 70 for electrical connection with the outside. Since the lead tab portions 41, 45 have a thin metal plate shape, the lead tab portions 41, 45 may protrude to the outside of the case 70 through a space between the first contact portion 73a and the second contact portion 73b. However, since the first contact portion 73a and the second contact portion 73b are to be sealed, the sealing of the first contact portion 73a and the second contacting portion 73b may be damaged due to interference with the lead tab portions 41, 45. To prevent the above, one of the first contact portion 73a and the second contact portion 73b may include a recessed portion 75 corresponding to the shape of the lead tab portions 41, 45.

Referring to FIG. 1, the lead tab portions 41, 45 may include the lead tabs 21, 22 that serve as terminals that electrically connect the electrode assembly 10 and the outside, and the lead films 16, 17 that surround regions of the lead tabs 21, 22 that overlap and come into contact with the case 70.

That is, the lead films 16, 17 may serve to bring the lead tabs 21, 22 into close contact with the first contact portion 73a and the second contact portion 73b so that the first contact portion 737 and the second contact portions 73b to be sealed better with the lead tabs 21, 22.

In order to manufacture the battery cell 100, first, the electrode assembly 10 and the lead tab portions 41, 45 electrically connected to the electrode assembly 10 may be disposed in the case 70. The electrode assembly 10 may be disposed in the accommodation space 76, and the lead tab portions 41, 45 may protrude to the outside of the case through the recessed portion 75.

Referring to FIG. 1, the recessed portion 75 may include a first recess 75a and a second recess 75b into which the lead tab portions 41, 45 are inserted, respectively.

Although FIG. 1 illustrates the lead tab portions 41, 45 protruding in opposite directions passing through the first recessed portion 75a and the second recessed portion 75b, this is only an example, and the first and second recessed portions 75a and 75b may be located in the same direction, and the lead tab portion 41, 45 may protrude in the same direction.

The direction in which the first electrode 101 and the second electrode 103 of the electrode assembly 10 are stacked is referred to as the stacking direction, and the directions perpendicular to each other among the directions perpendicular to the stacking direction are referred to as the first direction (or a X direction) and the second direction (or a Y direction), respectively. Therefore, the stacking direction may be a Z direction perpendicular to the X direction and the Y direction. The first direction and the second direction may be directions in which the lead tab portions 41, 45 protrude and directions perpendicular to the stacking direction and the first direction, respectively.

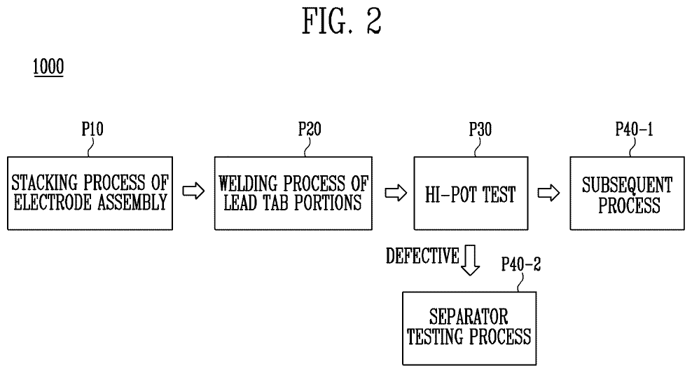

FIG. 2 illustrates an example of a process in which an inspection device according to the present disclosure is used in a manufacturing process of a battery.

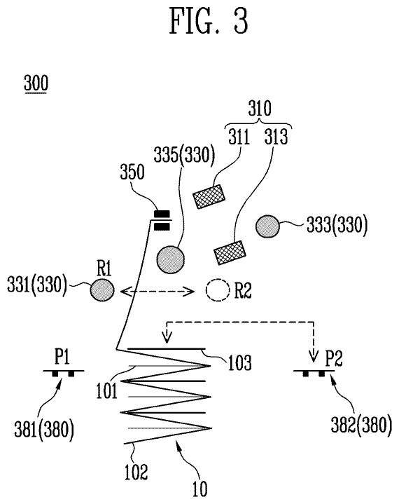

Referring to FIG. 2, a battery manufacturing system 1000 including a battery inspection apparatus 300 (refer to FIG. 3) according to the present disclosure may include a stacking process P10 of stacking the first electrode 101, the second electrode 103, and the separator 102 to form the electrode assembly 10, a welding process P20 of welding the electrode assembly 10 to electrically connect the lead tab portions 41, 45, and a withstand voltage testing process P30 (or a Hi-Pot Test) of testing a withstand voltage of the electrode assembly 10 coupled to the lead tab portion 41, 45.

The welding process P20 may be used when voltage is applied by connecting the positive and negative electrodes through the lead tab portions 41, 45 in the withstand voltage testing process.

In the withstand voltage testing process P30, the battery manufacturing system 1000 may apply a predetermined voltage to check whether the insulation of the electrode assembly 10 is abnormal. For example, the battery manufacturing system 1000 may apply a predetermined voltage of 150 V or more and 300 V, or less, to the negative electrode (-pole) of the lead tab portions 41, 45, and then may check the leakage current when grounding the positive electrode (+pole) to check whether there is an abnormality in insulation. When the separator 102 is not damaged, the leakage current may ideally be zero.

The electrode assembly 10 that has passed the withstand voltage testing process P30 may be moved for a disposing process P40-1 to be disposed in the case 70. In contrast, the electrode assembly 10 that has been judged as defective in the withstand voltage testing process P30, may be moved for a separator testing process P40-2 which disassembles the separator to confirm the damaged part for cause analysis.

The battery inspection apparatus 300 according to the present disclosure may be utilized in the separator testing process P40-2 among the processes included in the battery manufacturing system 1000.

Referring to FIG. 2, the present disclosure illustrates an example of the battery inspection apparatus 300 being used in an offline process rather than an in-line process. However, in contrast, the battery inspection apparatus 300 may also be used in the in-line process.

FIG. 3 schematically illustrates an example of the battery inspection apparatus 300 and a step of an inspection method of the battery inspection apparatus 300 according to the present disclosure.

The battery inspection apparatus 300 according to the present disclosure may include a grip 350 detachably fixed to the separator 102 located at the outermost layer of the electrode assembly 10 in the electrode assembly 10 formed by alternately stacking the first electrode 101 and the second electrode 103 having a different electrical polarity between the separator 102 in the predetermined stacking direction, and moving along a predetermined separation path to separate the separator 102, a separation unit 380 separating the first electrode 101 and the second electrode 103 from the electrode assembly 10 according to the separation of the separator 102, and a sensing unit 310 located in the separation path and sensing damage to electrical insulation in the separator 102 moved by the grip 350.

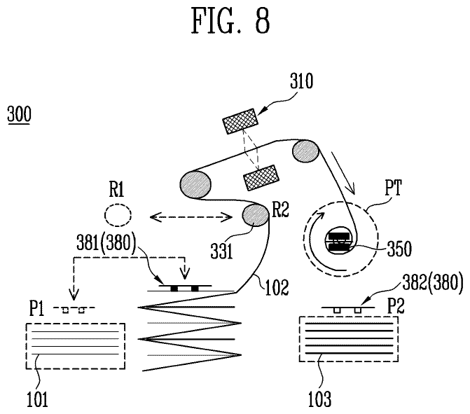

The grip 350 may grip the separator 102 and move the separator 102 to a predetermined target position PT (refer to FIG. 8). Since the separator 102 is moved by the grip 350, the grip 350 may pull the separator 102 with a predetermined tension. Subsequently, the separator 102 may eventually be separated or disassembled from the electrode assembly 10.

Referring to FIG. 3, the grip 350 may have the same shape as a gripper. That is, the grip 350 may grip an outermost layer of the separator 102 and move the separator 102 to the target position PT along the separation path.

FIG. 3 illustrates an example in which the separator 102 with a single long sheet-shape is folded in a zigzag. The first electrode 101 and the second electrode 103 may be alternately inserted between the zigzag-folded separator 102 to form the electrode assembly 10.

However, this is only an example, and the battery inspection apparatus 300 may also be used in the case where the electrode assembly 10 includes the separator 102 including a plurality of separators 102 and stacked in the stacking direction. However, in this case, unlike those shown in FIG. 3, the grip 350 may move the plurality of separators 102 one by one.

The separation unit 380 may separate the first electrode 101 and/or the second electrode 103 exposed externally along the stacking direction from the electrode assembly 10 when the separator 102 is separated. That is, the first electrode 101 and/or the second electrode 103 may be exposed externally one by one as the separation of the separator 102 proceeds and unfolds. Therefore, in order to separate the separator 102 from the electrode assembly 10, the separation of the first electrode 101 and the second electrode 103 may also be necessary.

The separation unit 380 may include a first electrode separation unit 381 that separates the first electrode 101 exposed externally along the stacking direction when the separator 102 is separated and a second electrode separation unit 382 that separates the second electrode 103 exposed externally along the stacking direction when the separator 102 is separated.

The first electrode separation unit 381 and the second electrode separation unit 382 may separate the first electrode 101 and the second electrode 103, respectively, using a pick and place method. That is, the first electrode separation unit 381 and the second electrode separation unit 382 may lift the first electrode 101 and the second electrode 103 by using negative pressure, and then move the first electrode 101 and the second electrode 103 to a predetermined first storage space P1 and a predetermined second storage space P2, respectively.

In addition to the pick-and-place method, another method may be used in the present disclosure in which the first electrode separation unit 381 and the second electrode separation unit 382 lift and move the first electrode 101 and the second electrode 103.

Considering that the first electrode 101 and the second electrode 103 are inserted in opposite directions between the zigzag-folded separator 102, when the first electrode 101 is separated from the second electrode 103, the first electrode 101 may be moved in different directions in the electrode assembly 10. The first electrode 101 and the second electrode 103 may be separately collected and stored. This is because when the damaged part of the separator 102 is detected, the first electrode 101 and the second electrode 103 adjacent to the damaged position may be inspected.

Alternatively, the first electrode 101 and the second electrode 103 may be separated in order to reuse the first electrode 101 and the second electrode 103. To this end, the first electrode separation unit 381 may stack the first electrode 101 in the first storage space P1, and the second electrode separation unit 382 may stack the second electrode 103 in the second storage space P2.

The sensing unit 310 may sense a region where electrical insulation is damaged in the separator 102 to be separated. In the present disclosure, the region where electrical insulation is damaged in the separator 102 is a concept that encompasses not only a region where the separator 102 has physical damage, but also a specific region where electrical insulation in the separator 102 is broken.

For example, the battery inspection apparatus 300 according to the present disclosure may disassemble an electrode assembly that has failed to pass a withstand voltage test (or a Hi-pot test) due to the inflow of foreign substances, electrode detachment, physical damage to the separator, or the like, to identify a damaged area (or an area with burn marks) in the separator 102.

The sensing unit 310 may include a first sensing unit 311 that senses one of both surfaces of the separator 102 moved by the grip 350, and a second sensing unit 313 that senses the other of the both surfaces of the separator 102.

This is because the damaged region in the separator 102 may appear on both surfaces of the separator 102 at the same time, such as when a hole is formed through the separator 102, but the damaged region in the separator 102 may be only on one of both surfaces of the separator 102.

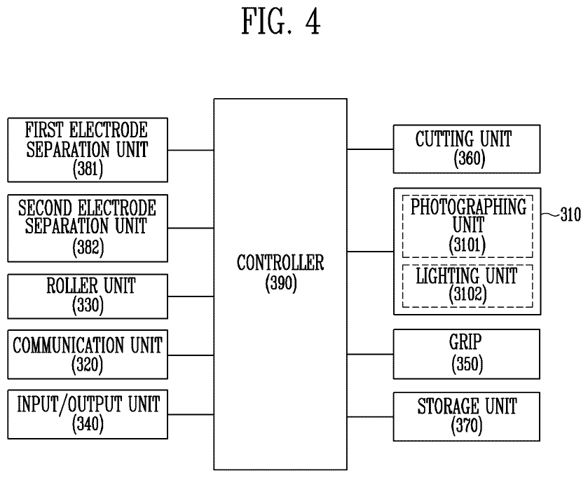

Meanwhile, in order to detect the damaged region in the separator 102, the sensing unit 310 may use a vision method. To this end, the first sensing unit 311 and the second sensing unit 313 may each include a photographing unit 3101 (refer to FIG. 4) for photographing the separator 102. When the first sensing unit 311 photographs one of both surfaces of the separator 102, the second sensing unit 313 may photograph the other surface of the separator 102.

In addition, the sensing unit 310 may further include a lighting unit 3102 (refer to FIG. 4) that emits light to the separator 102 moved by the grip 350. Through the lighting unit 3102, the first sensing unit 311 and the second sensing unit 313 may better sense the damaged area in the separator 102.

Meanwhile, referring to FIG. 3, the battery inspection apparatus 300 according to the present disclosure may further include a roller unit 330 to support movement of the separator 102 moved by the grip 350.

More specifically, the roller unit 330 may include a moving roller unit 331 that changes the position of the separator 102 separated by the grip 350 based on the first electrode 101 and the second electrode 103 exposed externally along the stacking direction when the separator 102 is separated.

The moving roller unit 331 may move between a first rotational position R1 and a second rotational position R2 along a direction parallel to the first electrode 101 and the second electrode 103 that is not yet separated from the electrode assembly 10.

In an embodiment, referring to FIG. 3, considering that the separator 102 folded in the zigzag shape is pulled and unfolded by the grip 350 when the second electrode 103 is separated, the moving roller unit 331 may move to the first rotational position R1 located closer to the first electrode separation unit 381 than the second electrode separation unit 382 in order to facilitate access to the second electrode 103.

In contrast, when the moving roller unit 331 separates the first electrode 101, the moving roller unit 331 may move to the second rotational position R2 located closer to the second electrode separation unit 382 than the first electrode separation unit 381.

In addition, the battery inspection apparatus 300 may guide the release of the separator 102 through the roller unit 330, facilitate the movement of the separator 102, and apply an appropriate tension to the separator 102. To this end, the roller unit 330 may further include a guide roller unit 335 that is located on the separation path and supports the separated separator 102, and a switching roller unit 333 that supports the direction of the separated separator 102 to be switched toward the target position PT.

On the other hand, FIG. 3 illustrates an example in which a region of the separator 102 located on an outermost side of the electrode assembly 10 is cut, and then one end of the cut separator is mounted on the grip 350. Referring to FIGS. 2 and 3, in order to inspect the electrode assembly 10 that has not passed the withstand voltage test, the inspection method of the battery inspection apparatus 300 according to the present disclosure may include a step of cutting the separator 102 located at the outermost side (or the outermost layer) of the electrode assembly 10 and then placing the separator 102 on the grip 350.

FIG. 4 is a control block diagram of the battery inspection apparatus 300 according to the present disclosure.

The battery inspection apparatus 300 according to the present disclosure may further include a controller 390. The controller 390 may control the separation unit 380, the grip 350, and the sensing unit 310.

The controller 390 may control the grip 350 so that the grip 350 grips the separator 102 and moves along the separation path.

The controller 390 may control the first electrode separation unit 381 and the second electrode separation unit 382 to separate and separate the first electrode 101 and the second electrode 103.

In addition, the controller 390 may detect the damaged region in the separator 102 through the sensing unit 310.

In addition, the controller 390 may control the roller unit 330. In particular, the controller 390 may change the position of the moving roller unit 331 according to the first electrode 101 and the second electrode 103.

Meanwhile, the battery inspection apparatus 300 according to the present disclosure may further include a storage unit 370 that stores information on the damaged area in the separator 102 obtained through the sensing unit 310, a communication unit 320 that transmits the information to the outside, and an input/output unit 340 that notifies an operator of the information. The controller 390 may further control the storage unit 370, the communication unit 320, and the input/output unit 340. The input/output unit 340 may receive a user's command or displaying a result of receiving and performing the user's command.

In addition, the battery inspection apparatus 300 according to the present disclosure may further include a cutting unit 360 for cutting a region of the separator 102 located at the outermost side of the electrode assembly 10 and mounting the cut unit 360 on the grip 350. The controller 390 may control the cutting unit 360 to cut a region of the separator 102 and allow the separator 102 to be mounted on the grip 350.

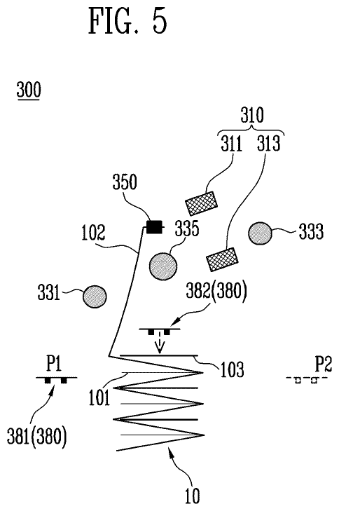

FIG. 5 schematically illustrates another step of the inspection method of the battery inspection apparatus 300 according to the present disclosure.

Referring to FIGS. 3 and 5, the battery inspection apparatus 300 according to the present disclosure may fix the grip 350 detachably to the separator 102 after the separator 102 is mounted on the grip 350. That is, the grip 350 may grip the separator 102. As a result, when the grip 350 moves along the separation path, the separator 102 may move along the grip 350, and thus may be separated from the electrode assembly 10.

Meanwhile, referring to FIG. 5, the grip 350 grips the separator 102 of the outermost layer, so that the second electrode 103 may exposed externally along the stacking direction. However, this may vary depending on the order in which the first electrode 101 and the second electrode 103 are stacked. For example, the first electrode 101 may be exposed before the second electrode 103.

When the second electrode 103 is exposed externally along the stacking direction, the controller 390 may control the second electrode separation unit 382 to pick the exposed second electrode 103 and place it in the second storage space P2. At this time, the first electrode separation unit 381 may be located away from the electrode assembly 10.

Referring to FIG. 5, the second electrode separation unit 382 moves as the second electrode 103 is exposed, so the moving roller unit 331 may support the separator 102 to be separated at the first rotational position R1 (refer to FIG. 3).

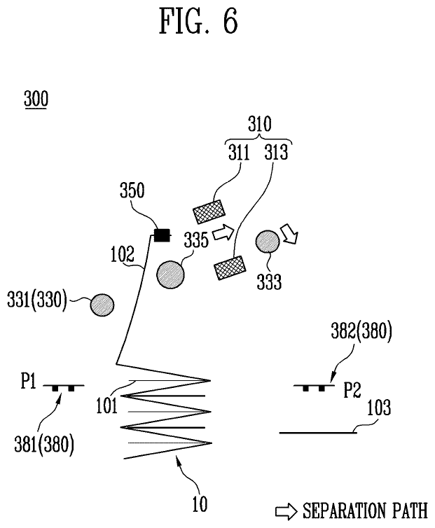

FIG. 6 schematically illustrates another step of the inspection method of the battery inspection apparatus 300 according to the present disclosure.

Referring to FIG. 6, the grip 350 and the separator 102 separated by the grip 350 may move along the separation path. The grip 350 may separate the separator 102 from the electrode assembly 10 without interruption while applying appropriate tension to the separator 102.

The separator 102 may pass through the sensing unit 310 while moving to be supported by the guide roller unit 335. More specifically, the separator 102 separated by the grip 350 may pass between the first sensing unit 311 and the second sensing unit 313. In this case, the controller 390 may detect the damaged area in the separator 102 through the first detection unit 311 and the second detection unit 313 and may calculate a corresponding position.

The separator 102 passing through the sensing unit 310 may be redirected by the switching roller unit 333 to move toward the target position PT (refer to FIG. 8).

Meanwhile, the second electrode separation unit 382 may move the exposed second electrode 103 to the second storage space P2 to be dropped.

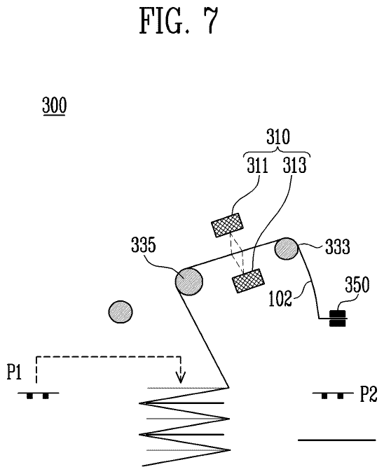

FIG. 7 schematically illustrates another step of the inspection method of the battery inspection apparatus 300 according to the present disclosure.

FIG. 7 illustrates an example in which the sensing unit 310 senses the damaged region in the separator 102 located in the sensing region of the sensing unit 310. When the separator 102 moved by the grip 350 passes through the sensing unit 310 located on the separation path, the sensing unit 310 may photograph the separator 102. The controller 390 may recognize the damaged area from the image acquired through the sensing unit 310 and confirm the location thereof.

On the other hand, after the second electrode 103 is separated, the controller 390 may move the first electrode separation unit 381 to the electrode assembly 10 to separate the first electrode 101 alternately arranged with the second electrode 103.

FIG. 8 schematically illustrates another step of the inspection method of the battery inspection apparatus 300 according to the present disclosure.

Referring to FIG. 8, the grip 350 may move the separator 102 to the predetermined target position PT (refer to FIG. 8) along the separation path.

In addition, at the target position PT, the grip 350 may wind only the separator 102 through rotation. When the separator 102 is folded in the zigzag shape, the length thereof may be relatively long, so that the space occupied by the separator 102 may be reduced by rotating the grip 350 at the target position PT.

When the electrode assembly 10 includes the plurality of separators 102 instead of one separator 102, the grip 350 may separate only the plurality of separators 102 from the electrode assembly 10 and move the plurality of separators 102 to the target position.

Meanwhile, the grip 350 may move to the predetermined target position PT along the separation path, and then wind the separator 102 moved by the grip 350 through rotation.

While the grip 350 winds the separator 102 separated by the grip 350 through rotation, the sensing unit 310 may sense a damaged area in the separator 102 newly separated from the electrode assembly 10.

Referring to FIG. 8, the first electrode separation unit 381 may access the electrode assembly 10 to separate the first electrode 101 exposed along the stacking direction. To this end, the controller 390 may move the moving roller unit 331 to the second rotational position R2. Therefore, the moving roller unit 331 may prevent interference between the separator 102 to be separated and the first electrode separation unit 381 and/or the second electrode separation unit 382.

Meanwhile, referring to FIG. 8, the first electrode separation unit 381 may drop and stack the separated first electrode in the first storage space P1. The second electrode separation unit 382 may drop and stack the separated second electrode in the second storage space P2. The first electrode 101 and the second electrode 103 may be stored for investigation for cause analysis related to the damaged area of the separator 102. Alternatively, the first electrode 101 and the second electrode 103 may be separately stored to be reused for assembly of another electrode assembly 10 in the future.

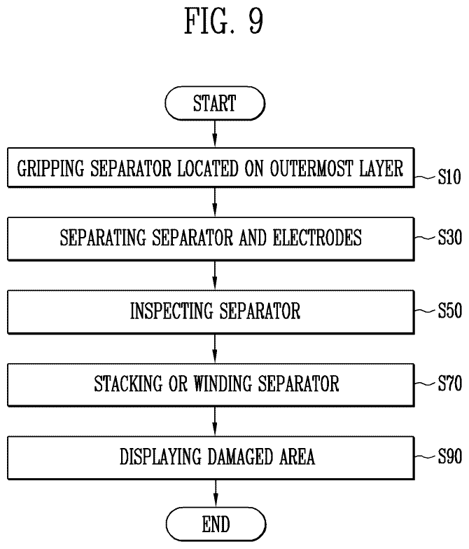

FIG. 9 is a flowchart illustrating the inspection method of the battery inspection apparatus 300 according to the present disclosure.

More specifically, FIG. 9 is a flowchart illustrating the inspection method of the battery inspection apparatus 300 described with reference to FIGS. 3 and 5 to 8.

The inspection method of the battery inspection apparatus 300 according to the present disclosure may include a step S10 of gripping a portion of the separator 102 located on the outermost layer of the electrode assembly 10 by the grip 350, a step S30 of separating the first electrode 101 and the second electrode 103 through the separation unit 380 according to the separation of the separator 102 by the grip 350, and a step S50 of inspecting the electrical insulation damage in the separator 102 moved by the grip 350 through the sensing unit 310 located on the separation path.

In the step S30 of separating the first electrode 101 and the second electrode 103 through the separation unit 380, the inspection method of the battery inspection apparatus 300 according to the present disclosure may separate the first electrode 101 exposed externally along the stacking direction through the first electrode separation unit 381 and the second electrode separation unit 382, respectively.

The inspection method of the battery inspection apparatus 300 according to the present disclosure may further include a step S70 of stacking or winding the separator 102 moved by the grip 350 through the grip 350.

The step S70 of stacking or winding the separator 102 may be performed simultaneously with the step S30 of separating the first electrode 101 and the second electrode 103 through the separation unit 380 and the step S50 of inspecting the electrical insulation damage in the separator 102. That is, when a portion of the separator 102 reaches the target position PT and is wound by the grip 350, another portion of the separator 102 may be separated from the electrode assembly 10, and another portion of the separator 102 may be inspected for the electrical insulation damage through the sensing unit 310 while moving along the separation path.

In addition, the inspection method of the battery inspection apparatus 300 according to the present disclosure may further include a step S90 of displaying information including an area in which electrical insulation is damaged in the separator 102 sensed by the sensing unit 310.

The information including the region where the electrical insulation is damaged may be displayed in the input/output unit 340 (refer to FIG. 4), stored in the storage unit 370 (refer to FIG. 3), or transmitted to another terminal device or control device through the communication unit 320 (refer to FIG. 5).

The information including the region where the electrical insulation is damaged may include coordinates in the first direction and the second direction perpendicular to the stacking direction and perpendicular to each other, and a stacking order of the first electrode 101 and the second electrode 103 along the stacking direction.

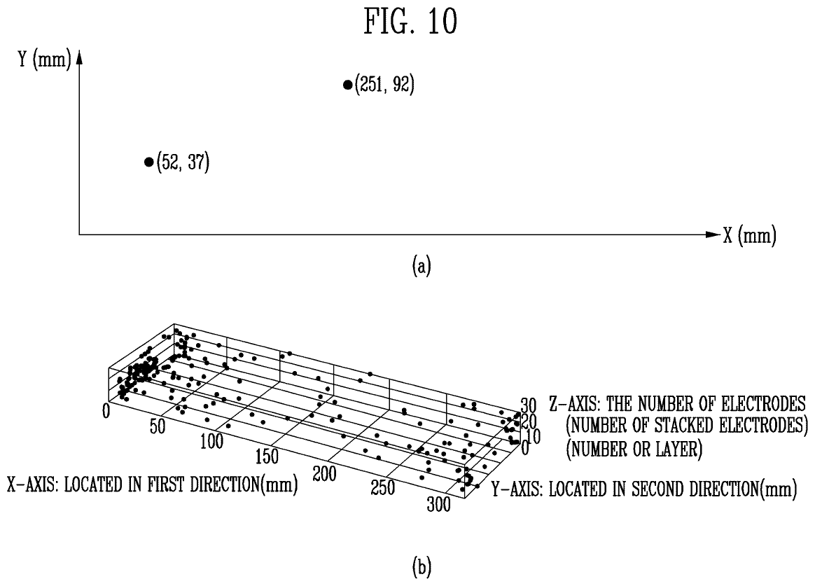

FIG. 10 illustrates the results according to the inspection method of the battery inspection apparatus 300 according to the present disclosure.

In FIG. 10, (a) is a two-dimensional view of the area where the electrical insulation is damaged through the sensing unit 310 in the separator 102 or the portion of the separator 102 corresponding to one of the first electrode 101 and the second electrode 103 stacked on the electrode assembly 10.

Referring to (a) of FIG. 10, the X direction is the first direction in which the lead tab portions 41, 45 protrude, and the Y direction is the second direction perpendicular to the stacking direction and the first direction. Therefore, X and Y may refer to two-dimensional coordinates of the portion of the separator 102 forming one layer in the electrode assembly 10 or the separator 102 as a plane.

For example, (a) FIG. 10 illustrates two damaged areas in one layer of the separator 102. In FIG. 10, millimeters are used as the units of an X-axis and a Y-axis, but this is only an example, and other units may be used.

In FIG. 10, (b) illustrates the region where the electrical insulation is damaged in the separator 102 in three-dimensions according to the order in which they are stacked in the electrode assembly 10.

Referring to (b) of FIG. 10, the information of one layer of separator obtained in (a) of FIG. 10 is illustrated in three-dimensions with the stacking order of separator as a Z-axis. Therefore, the Z-axis may refer to the number of electrodes according to the stacked order of the first electrode 101 and/or the second electrode 103 along the stacking direction, or the stacking order.

Through this, the operator may notice which position of the separator 102 is damaged when the electrode assembly 10 has been judged to be defective in the Hi-Pot test (P3, refer to FIG. 2).

Since the present disclosure may be implemented in various forms, the scope of rights is not limited to the above-described embodiments. Therefore, if the modified embodiment includes the elements of the claims of the present disclosure, it should be considered to fall within the scope of the present disclosure.

What is claimed is:

1. A battery inspection apparatus comprising:
a grip detachably fixed to a separator located at an outermost layer of an electrode assembly and separating the separator by moving along a predetermined separation path in the electrode assembly, the electrode assembly being formed by alternately stacking a first electrode and a second electrode having a different electrical polarity from the first electrode between the separator in a predetermined stacking direction;
a separation unit separating the first electrode and the second electrode from the electrode assembly according to separation of the separator; and
a sensing unit located in the separation path and sensing damage to electrical insulation in the separator moved by the grip.

2. The battery inspection apparatus according to claim 1, wherein the sensing unit includes:
a first sensing unit configured to sense one surface of both surfaces of the separator moved by the grip; and
a second sensing unit configured to sense an other surface of the both surfaces of the separator.

3. The battery inspection apparatus according to claim 2, wherein each of the first sensing unit and the second sensing unit includes a photographing unit configured to photograph the separator.

4. The battery inspection apparatus according to claim 1, wherein the grip moves to a predetermined target position along the separation path and winds the separator moved by the grip through rotation.

5. The battery inspection apparatus according to claim 1, wherein the separation unit includes:
a first electrode separation unit configured to separate the first electrode exposed externally along the stacking direction when the separator is separated; and
a second electrode separation unit configured to separate the second electrode exposed externally along the stacking direction when the separator is separated.

6. The battery inspection apparatus according to claim 5, wherein the first electrode separation unit and the second electrode separation unit separate the first electrode and the second electrode, respectively, by a pick and place method.

7. The battery inspection apparatus according to claim 5, wherein the first electrode separation unit and the second electrode separation unit are configured to move the first electrode and the second electrode in different directions from each other when the first electrode and second electrode are separated.

8. The battery inspection apparatus according to claim 5, wherein the first electrode separation unit stacks the first electrode in a predetermined first storage space, and
wherein the second electrode separation unit stacks the second electrode in a predetermined second storage space.

9. The battery inspection apparatus according to claim 1, further comprising:
an input/output unit receiving a user's command or displaying a result of receiving and performing the user's command; and
a control unit controlling the grip, the separating unit, the sensing unit, and the input/output unit,
wherein the control unit is configured to detect an area in which electrical insulation is damaged in the separator by the sensing unit, and display information on the damaged area by the input/output unit.

10. The battery inspection apparatus according to claim 1, further comprising a roller unit configured to support movement of the separator along the separation path.

11. The battery inspection apparatus according to claim 10, wherein the roller unit includes a moving roller unit configured to change a position of the separator separated by the grip based on the first electrode and the second electrode exposed externally along the stacking direction when the separator is separated.

12. An inspection method of a battery apparatus, wherein the battery apparatus tests an electrode assembly formed by alternately stacking a first electrode and a second electrode having a different electrical polarity from the first electrode between a separator in a predetermined stacking direction, the method comprising:
gripping a portion of the separator located on an outermost layer of the electrode assembly by a grip;
separating the first electrode and the second electrode through a separation unit according to separation of the separator by the grip; and
inspecting damage to electrical insulation in the separator moved by the grip through a sensing unit located in a separation path.

13. The method of claim 12, wherein in the separating of the first electrode and the second electrode through the separation unit, the first electrode and the second electrode exposed externally along the stacking direction are separated through a first electrode separation unit separating the first electrode and a second electrode separation unit separating the second electrode in the separation unit, respectively.

14. The method of claim 12, further comprising, stacking or winding the separator moved by the grip through the grip.

15. The method of claim 14, further comprising, displaying information including a region where electrical insulation is damaged in the separator through the sensing unit.

16. The method of claim 15, wherein the information including a region where electrical insulation is damaged includes coordinates in a first direction and a second direction perpendicular to the stacking direction and perpendicular to each other, and a stacking order of the first electrode and the second electrode in the stacking direction.
